(19) United States
(12) Patent Application Publication
(10) Pub. No.: US 2025/0283212 A1
(43) Pub. Date: Sep. 11, 2025

(54) INHERENTLY SELECTIVE THERMAL ATOMIC LAYER DEPOSITION OF COPPER METAL FILMS

(71) Applicant: WAYNE STATE UNIVERSITY, Detroit, MI (US)

(72) Inventors: Charles H. WINTER, Bloomfield Hills, MI (US); Thomas ROSE-GRAY, Marine City, MI (US)

(73) Assignee: WAYNE STATE UNIVERSITY, Detroit, MI (US)

(21) Appl. No.: 18/601,338

(22) Filed: Mar. 11, 2024

(51) Int. Cl. C23C 16/04; C23C 16/02; C23C 16/18; C23C 16/455

(52) U.S. Cl. CPC C23C 16/04; C23C 16/0254; C23C 16/18; C23C 16/45527; C23C 16/45553

(57) ABSTRACT

A method for depositing a copper metal coating on a substrate's surface includes providing a substrate with a first face and a second face. The first face includes at least one exposed surface composed of a metallic material and at least one exposed surface composed of a non-metallic material. The substrate is contacted with a vapor of a copper-containing compound and hydrazine vapor at a sufficient temperature to preferentially form a copper metal coating on the surface composed of a metallic material as compared to the exposed surface composed of a non-metallic material.

### TECHNICAL FIELD

In at least one aspect, the present invention is related to a method for selectively depositing copper metal films.

### BACKGROUND

Copper is used as a conductor in microelectronics devices. Selective copper deposition is necessary for precise and controlled copper deposition on specific substrate areas in such devices. Atomic Layer Deposition (ALD) has been used for this purpose.

Selective copper deposition can be a complicated and expensive process. A typical ALD process for depositing copper metal involves the preparation of target surfaces in the semiconductor device with chemicals that promote the growth of copper metal films, while areas not prepared with such chemicals do not grow copper metal films. Alternatively, chemical modifiers are applied to non-target areas of the substrate to prevent copper deposition. These modifiers block the precursor from adsorbing or reacting with the surface, thus enhancing the selectivity of the deposition process.

Accordingly, there is a need for improved methods for selectively depositing copper metal films on a substrate.

### SUMMARY

In at least one aspect, a method for depositing a copper metal coating on the surface of a substrate is provided. The method includes a step of providing a substrate having a first face and a second face. The first face includes at least one exposed surface composed of a metallic material and at least one exposed surface composed of a non-metallic material. The substrate is contacted with a vapor of a copper-containing compound and a hydrazine vapor and/or an alkyl-substituted hydrazine vapor at a sufficient temperature to preferentially form a copper metal coating on the at least one surface composed of a metallic material as compared to the at least one exposed surface composed of a non-metallic material.

In another aspect, ALD provides a method for depositing a copper metal coating on the surface of a substrate. Characteristically, the substrate includes a first face and a second face. The first face includes at least one exposed surface composed of a metallic material and at least one exposed surface composed of a non-metallic material. The method includes an atomic layer deposition cycle including steps of contacting the substrate with or without a coating thereon with a hydrazine vapor and/or an alkyl-substituted hydrazine vapor and contacting the substrate with or without a coating thereon with a vapor of a copper-containing compound at a temperature from 225 to 300° C. to preferentially form a copper metal coating on the surface composed of a metallic material as compared to the exposed surface composed of a non-metallic material. These steps are repeated for a sufficient number of cycles to form a predetermined thickness of the copper metal coating.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIG. 1A. Schematic flowchart depicting the selective deposition of copper metal films.

FIG. 1B. Schematic of a deposition system for depositing copper metal by CVD.

FIG. 1C. Schematic of a deposition system for depositing copper metal by ALD.

FIG. 2. Chemical structures of diketones relevant to the selective deposition of copper metal films.

FIG. 3. Copper saturation plot of copper metal film growth rate versus copper pulse rate.

FIG. 4. Hydrazine saturation plot of copper metal film growth rate versus hydrazine pulse rate.

FIG. 5. Bar chart showing the effect of purge times on the copper metal film growth.

FIG. 6. Plots of copper metal film growth rate versus temperature.

FIG. 7. Bar chart showing the selective deposition of copper metal films on various substrates.

FIG. 8. Bar chart showing the selective deposition of copper metal films on various substrates.

FIG. 9. Plots of K alpha counts versus the number of cycles demonstrating the selective deposition of copper metal films.

FIG. 10. XPS analysis for copper deposition on TiN.

FIG. 11. XPS analysis for copper deposition on Ru.

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: all R groups (e.g. Rᵢ where i is an integer) include hydrogen, alkyl, lower alkyl, C₁₋₆ alkyl, C₆₋₁₀ aryl, C₆₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups M is a metal atom (e.g., Na, K, Li, etc.) and L- is a counter anion (e.g., Cl—, Br—, tosylate, etc.); single letters (e.g., “n” or “o”) are 1, 2, 3, 4, or 5; in the compounds disclosed herein including compounds described by formula or by name, a CH bond can be substituted with alkyl, lower alkyl, C₁₋₆ alkyl, C₆₋₁₀ aryl, C₆₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups M is a metal atom (e.g., Na, K, Li, etc.); percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

The term “alkyl” refers to C₁₋₂₀ inclusive, linear (i.e., “straight-chain”), branched, saturated or at least partially and in some cases fully unsaturated (i.e., alkenyl and alkynyl) hydrocarbon chains, including for example, methyl, ethyl, propyl, isopropyl, butyl, isobutyl, tert-butyl, pentyl, hexyl, octyl, ethenyl, propenyl, butenyl, pentenyl, hexenyl, octenyl, butadienyl, propynyl, butynyl, pentynyl, hexynyl, heptynyl, and allenyl groups. “Branched” refers to an alkyl group in which a lower alkyl group, such as methyl, ethyl or propyl, is attached to a linear alkyl chain. “Lower alkyl” refers to an alkyl group having 1 to about 8 carbon atoms (i.e., a C₁₋₈ alkyl), e.g., 1, 2, 3, 4, 5, 6, 7, or 8 carbon atoms. “Higher alkyl” refers to an alkyl group having about 10 to about 20 carbon atoms, e.g., 10, 11, 12, 13, 14, 15, 16, 17, 18, 19, or 20 carbon atoms.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The phrase “composed of” means “including” or “comprising.” Typically, this phrase is used to denote that an object is formed from a material.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits. In the specific examples set forth herein, concentrations, temperature, and reaction conditions (e.g. pressure, pH, etc.) can be practiced with plus or minus 50 percent of the values indicated rounded to three significant figures. In a refinement, concentrations, temperature, and reaction conditions (e.g., pressure, pH, etc.) can be practiced with plus or minus 30 percent of the values indicated rounded to three significant figures of the value provided in the examples. In another refinement, concentrations, temperature, and reaction conditions (e.g., pH, etc.) can be practiced with plus or minus 10 percent of the values indicated rounded to three significant figures of the value provided in the examples.

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

Throughout this application, where publications are referenced, the disclosures of these publications in their entirety are hereby incorporated by reference into this application to more fully describe the state of the art to which this invention pertains.

A metallic material refers to a substance or compound that exhibits characteristic properties of metals, including high electrical and thermal conductivity, malleability, ductility, and a shiny appearance. This category encompasses pure elemental metals, such as iron, copper, and aluminum, as well as metal alloys, which are combinations of metals, such as steel (an alloy of iron and carbon), brass (an alloy of copper and zinc), and bronze (an alloy of copper and tin). Additionally, the definition extends to include metal-like compounds and materials, such as titanium nitride (TiN), which, despite not being pure metals, exhibit similar properties such as high hardness, thermal conductivity, and a metallic luster.

### Abbreviations

“acac” means acetylacetonate,
“ALD” means atomic layer deposition.
“btfac” means benzotrifluoroacetylacetonate.
“bzac” means benzoylacetonate.
“CVD” means chemical vapor deposition.
“dmhd” means dimethylheptanedionate.
“fdh” means trifluorodimethylhexanedionate
“fod” means fluorinated octanedionate.
“hfac” means hexafluoroacetylacetonate.
“ofac” means octafluorohexanedionate.
“thd” means tetramethylheptanedionate.
“tfac” means trifluoroacetylacetonate.

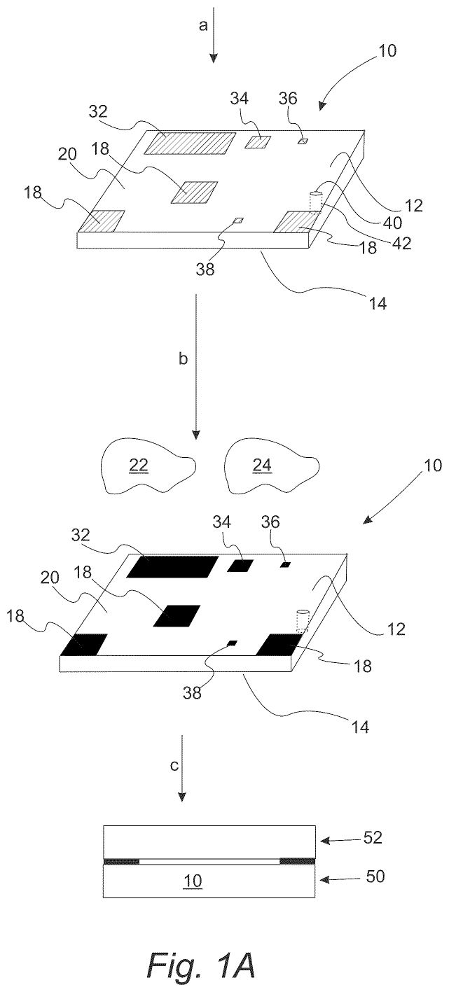

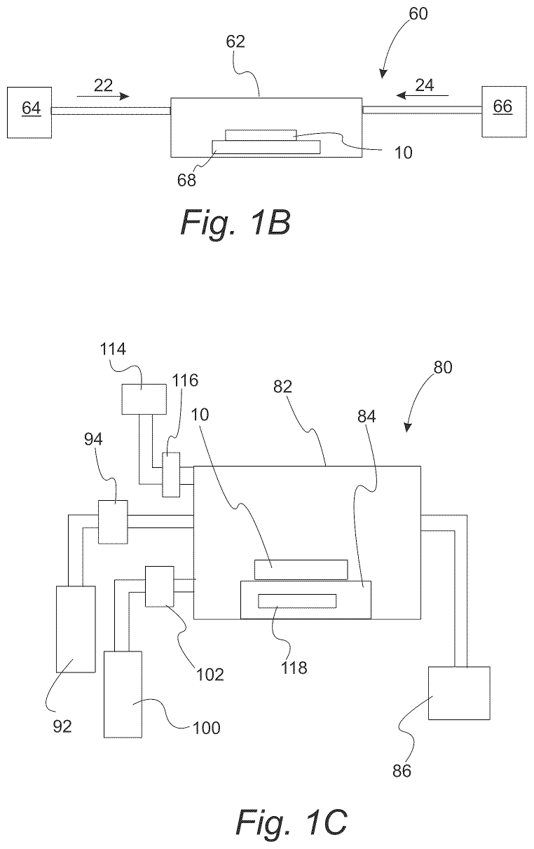

Referring to FIG. 1A, a schematic flow chart of a method for depositing a coating on the surface of a substrate is provided. In step a), substrate 10, which defines a first face 12 and a second face 14, is provided. Characteristically, the first face 12 has at least one exposed surface 18 composed of a metallic material and at least one exposed surface 20 composed of a non-metallic material. In step b), the substrate 10 is contacted with a vapor of a copper-containing compound 22 and a hydrazine vapor and/or an alkyl-substituted hydrazine 24 at a sufficient temperature to preferentially form a copper metal coating 26 on the surface 18 composed of a metallic material as compared to the exposed surface 20 composed of a non-metallic material. In a refinement, the alkyl-substituted hydrazine is a C₁₋₆ alkyl-substituted hydrazine. Alternatively, an alkyl amine or ammonia can be used along with or instead of the alkyl-substituted hydrazine 24. The alkyl amine can be a primary, secondary, or tertiary alkyl amine where each alkyl group is a C₁₋₆ alkyl group. In a refinement, the sufficient temperature is from 150 to 300° C. In some variations, the sufficient temperature is at least 120° C., 130° C., 140° C., 150° C., 160° C., 170° C., 180° C., 190° C., or 200° C., and at most 350° C., 340° C., 330° C., 320° C., 310° C., 300° C., 310° C., 300° C., 290° C., 280° C., or 270° C.

In another aspect, the first face 12 defines a plurality of macrostructures 32, microstructures 34, and/or nanostructures 36 that are selectively filled and/or coated with the copper metal coating. In a refinement, the first face 12 defines a plurality of nanofeatures 38 that are selectively filled and/or coated with the copper metal coating.

In another aspect, the first face 12 defines a plurality of dimples 40 of metallic material that are part of electrically conductive vias 42. In a refinement, the method further includes a step c) of polishing the first face 12 to form the plurality of dimples 40 before contacting the substrate with a vapor of a copper-containing compound and hydrazine or an alkyl-substituted hydrazine 22.

In another aspect, the substrate is part of a first microelectronic device 50. In a refinement, the method further includes a step c) of attaching the first microelectronic device 50 to a second microelectronic device 52 such that copper metal coating aligns with an electrically conductive layer in the second microelectronic device wherein the copper metal coating is configured to mitigate slight misalignments between layers.

In another aspect, a ratio of copper metal thickness on the at least one exposed surface composed of a metallic material to copper metal thickness on the at least one exposed surface composed of a non-metallic material is greater than 4:1. In a refinement, a ratio of copper metal thickness on the at least one exposed surface composed of a metallic material to copper metal thickness on the at least one exposed surface composed of a non-metallic material is greater than 10:1. In some refinements, a ratio of copper metal thickness on the at least one exposed surface composed of a metallic material to copper metal thickness on the at least one exposed surface composed of a non-metallic material is greater than, in increasing order of preference, 2:1, 3:1, 4:1, 5:1, 6:1, 7:1, 8:1, 9:1, or 10:1. Typically, a ratio of copper metal thickness on the at least one exposed surface composed of a metallic material to copper metal thickness on the at least one exposed surface composed of a non-metallic material is less than, in increasing order of preference, 12:1, 13:1, 14:1, 15:1, 16:1, 17:1, 18:1, 19:1, 20:1, 100:1, or higher.

In another aspect, the method of FIG. 1A is performed in a chemical vapor deposition reactor in which the vapor of a copper-containing compound 22 is reacted with the hydrazine vapor or an alkyl-substituted hydrazine 24 at the temperatures specified above to selectively form a copper metal film onto substrate 10. The CVD reaction can be conducted at atmospheric (e.g., about 760 torr) or reduced pressures (e.g., 100 mTorr to 20 Torr). FIG. 1B provides a schematic of a CVD system for selectively depositing copper metal films. CVD system 60 includes a reaction chamber 62. Copper-containing compound 22 is introduced from copper compound source 64 while the hydrazine vapor or an alkyl-substituted hydrazine 24 is introduced from hydrazine source 66 above to selectively form a copper metal film onto substrate 10. Substrate 10 is heated by heater 68.

In another aspect, the method of FIG. 1A includes an ALD deposition cycle that includes a step a′) of contacting the substrate with or without a coating thereon with the hydrazine vapor. In other words, step a′) is applicable to the first deposition cycle when the substrate is uncoated and to subsequent cycles as the coating is being built up. The deposition cycle further includes a step b′) of contacting the substrate with or without a coating thereon with the vapor of the copper-containing compound. Advantageously, these two steps are repeated for a sufficient number of cycles to form a predetermined thickness of the copper metal coating. Typically, the number of cycles can be from about 500 to 5000 cycles. In a refinement, the atomic layer deposition cycle further includes a first purging step with an inert gas after step a′) and a second purging step with an inert gas after step b′). In a further refinement, this purging step is performed for each deposition cycle. As set forth above, the substrate includes a first face and a second face, the first face having at least one exposed surface composed of a metallic material and at least one exposed surface composed of a non-metallic material.

With reference to FIG. 1C, ALD deposition system 80 includes reaction chamber 82, substrate holder 84, and vacuum pump 86. Typically, the substrate is heated via heater 68. Virtually any substrate may be coated as is well known by one skilled in the art of ALD. Surprisingly, the method of this variation is found to selectively deposit a copper metal layer on substrates 10 as set forth above. The method has a deposition cycle comprising contacting substrate 10 with a vapor of a copper metal-containing compound 22 as set forth above. In particular, the vapor of copper metal-containing compound 22 is introduced from precursor source 92 into reaction chamber 82 for a first predetermined pulse time. Typically, the first predetermined pulse time can be from 1 second to 20 seconds. The first pulse time is controlled via control valve 94. The method further comprises introducing the hydrazine vapor or an alkyl-substituted hydrazine 24 into reaction chamber 82 for a second predetermined pulse time from hydrazine source 100. Typically, the second predetermined pulse time can be from 0.05 seconds to 5 seconds. The second predetermined pulse time is controlled via control valve 102. The reduced pressure of chamber 82 is maintained by vacuum pump 86. In a variation of the present embodiment, the method further comprises removing at least a portion of the vapor of the copper metal-containing compound that is lingering in the gas phase (i.e., has not adsorbed or reacted with the substrate) from the vicinity of the substrate before introducing the hydrazine vapor and removing at least a portion of the vapor of the hydrazine vapor from the vicinity of the substrate. The copper metal-containing compound and the hydrazine vapor are removed in purging steps by introducing a purge gas from purge source 114 into reaction chamber 82 for a predetermined purge time. Typically, the predetermined purge times can be from 1 to 20 seconds. The purge time is controlled by control valve 116. Heater 118 can be used to heat substrate 10 to the temperatures set forth above.

In another aspect, the metallic material is selected from the group consisting of copper, cobalt, TiN, TaN, and ruthenium. In a refinement, the non-metallic material is selected from the group consisting of high-K materials, low K-materials, ultra-low-K materials, and combinations thereof. High-K dielectric materials are materials with a dielectric constant greater than about 3.9. Examples of High-K dielectric materials include hafnium oxide (HfO₂), zirconium oxide (ZrO₂), and titanium oxide (TiO₂). Low-K materials are materials with dielectric constants between about 2.5 and 3.9. Examples of low-k dielectric materials include silicon dioxide (SiO₂), fluorinated silica glass, and organosilicate glass. Ultra-low-K (ULK) materials are materials with dielectric constants below 2.5. Examples of Ultra-low-K (ULK) materials include porous SiO₂ and porous organosilicate glasses. In a refinement, the non-metallic material is selected from the group consisting of silicon with a native oxide, silicon with surface Si—H bonds, silicon oxide, and combinations thereof.

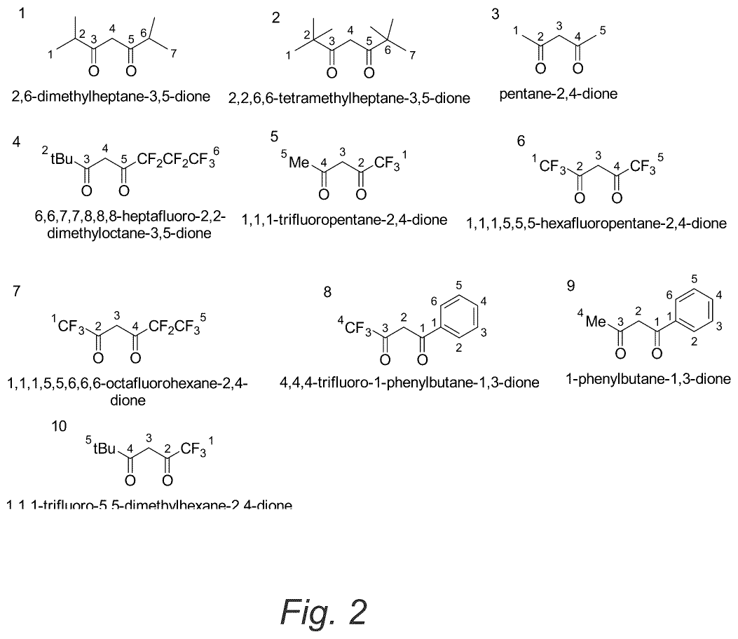

In another aspect, the copper-containing compound is a copper diketonate and or a copper diketone. The copper in the diketonate or diketone can be Cu(II) or Cu(I). An example of a diketonate is acetylacetonate (acac). In a refinement, the diketonate includes one or more neutral ligands. In a refinement, the copper-containing compound is selected from the group consisting of Cu(II) 2,6-dimethylheptane-3,5-dionate; Cu(II)2,2,6,6-tetramethylheptane-3,5-dionate; Cu(II) pentane-2,4-dionate; Cu(II) 6,6,7,7,8,8,8-heptafluoro-2,2-dimethyloctane-3,5-dionate; Cu(II) 1,1,1-trifluoropentane-2,4-dionate; Cu(II) 1,1,1,5,5,5-hexafluoropentane-2,4-dionate; Cu(II) 1,1,1,5,5,6,6,6-octafluorohexane-2,4-dionate; Cu(II) 4,4,4-trifluoro-1-phenylbutane-1,3-dionate; Cu(II) 1-phenylbutane-1,3-dionate; Cu(II) 1,1,1-trifluoro-5,5-dimethylhexane-2,4-dionate; and combinations thereof. It should be appreciated that these compounds with or without neutral ligands are contemplated with this list of compounds. In another refinement, the copper-containing compound is selected from the group consisting of Cu(I) 2,6-dimethylheptane-3,5-dionate; Cu(I)2,2,6,6-tetramethylheptane-3,5-dionate; Cu(I) pentane-2,4-dionate; Cu(I) 6,6,7,7,8,8,8-heptafluoro-2,2-dimethyloctane-3,5-dionate; Cu(I) 1,1,1-trifluoropentane-2,4-dionate; Cu(I) 1,1,1,5,5,5-hexafluoropentane-2,4-dionate; Cu(I) 1,1,1,5,5,6,6,6-octafluorohexane-2,4-dionate; Cu(I) 4,4,4-trifluoro-1-phenylbutane-1,3-dionate; Cu(I) 1-phenylbutane-1,3-dionate; Cu(I) 1,1,1-trifluoro-5,5-dimethylhexane-2,4-dionate; and combinations thereof. FIG. 2 provides the structures of the relevant diketones, while Table 1 provides the properties of diketones. It should be appreciated that these compounds with or without neutral ligands are contemplated with this list of compounds.

TABLE 1
Properties of diketonates.

| | | MP | Decomp | Sub | Sub |
|---|---|---|---|---|---|
| # | Name | (° C.) | (° C.) | (° C.) | Yield |
| 3 | Cu(acac)₂ | 286-288 | 300 | 160 | 89.7% |
| 2 | Cu(thd)₂ | 198-200 | 300-302 | 120 | 98.4% |
| 4 | Cu(fod)₂ | 83-85 | 234-236 | 100 | 97.8% |
| 5 | Cu(tfac)₂ | 196-198 | 239-241 | 140 | 97.3% |
| 6 | Cu(hfac)₂ | 97-99 | Boiled Out | 70 | 95.8% |
| 1 | Cu(dmhd)₂ | 128-130 | 294-295 | 120 | 88.2% |
| 7 | Cu(ofac)₂ | 60-62 | 97-99 | 40 | 97.6% |
| 8 | Cu(btfac)₂ | 251-253 | 292-294 | 170 | 48.2% |
| 9 | Cu(bzac)₂ | 151-153 | 151-153 | N/A | N/A |
| 10 | Cu(fdh)₂ | 96-98 | 251-253 | 140 | 97.6% |

In another aspect, the copper-containing compound is a Cu(I) diketonate that includes a stabilizing ligand. In a refinement, the stabilizing ligand is CH₂=CHSiMe₃. An example of a stabilized compound is Cu(I)(hexafluoroacetylacetonate)(CH₂=CHSiMe₃), which is a widely used Cu CVD precursor.

In another aspect, there is a molar excess of nitrogen-containing compounds (e.g., hydrazine and/or alkyl amines and/or ammonia) over copper-containing compounds. In a refinement, the molar ratio of nitrogen-containing compounds (e.g., hydrazine and/or alkyl amines and/or ammonia) to copper-containing compounds is at least 0.6:1, 0.8:1, 1:1, 1.2:1, 1.5:1, 2:1, 3:1, or 5:1. Typically, the molar ratio of nitrogen-containing compounds (e.g., hydrazine and/or alkyl amines and/or ammonia) to copper-containing compounds is at most 100:1, 50:1, 30:1, 20:1, 15:1, 10:1, or 5:1.

The following examples illustrate the various embodiments of the present invention. Those skilled in the art will recognize many variations that are within the spirit of the present invention and scope of the claims.

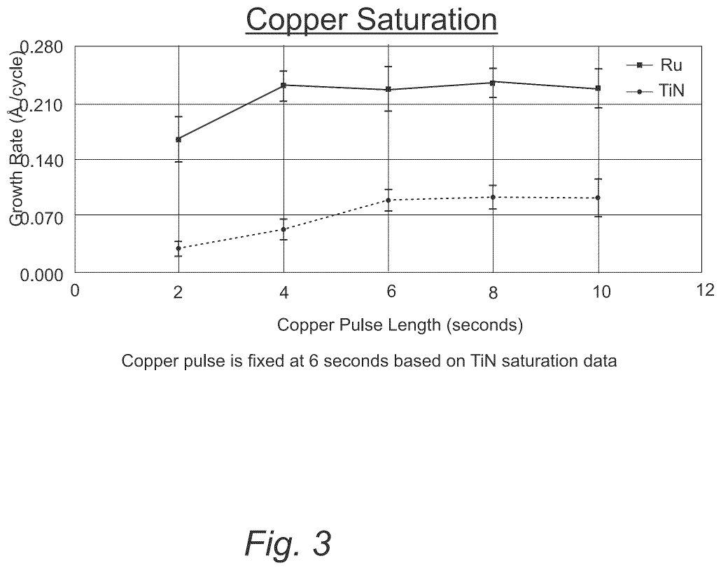

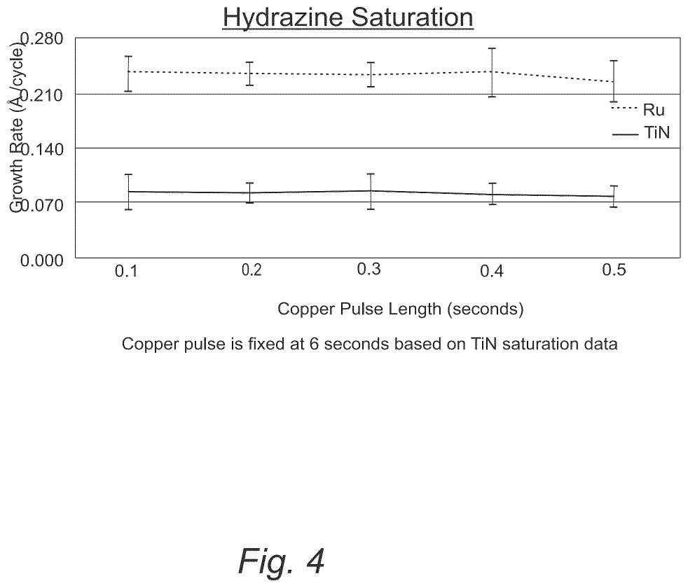

Copper metal films were deposited onto various metal and metallic surfaces to demonstrate conditions for selective deposition. FIG. 3 provides a copper saturation plot of copper metal film growth rate versus copper pulse rate. The copper films were deposited from Cu(thd)₂ (at a source temperature of 140° C.) and hydrazine at a temperature of 225° C. for 1000 cycles. After each pulse of Cu(thd)₂, a purge of about 10 seconds is applied. The hydrazine pulses were about 0.5 seconds with a purge pulse of about 10 s. Similarly, FIG. 4 provides a hydrazine saturation plot of copper metal film growth rate versus copper pulse rate. The copper films were deposited from Cu(thd)₂ (at a source temperature of 140° C.) and hydrazine at a temperature of 225° C. for 1000 cycles. Each pulse of Cu(thd)₂, was set to about 6 seconds. After each pulse of Cu(thd)₂, a purge of about 10 s is applied. After each hydrazine pulse, a purge pulse of about 10 seconds is applied.

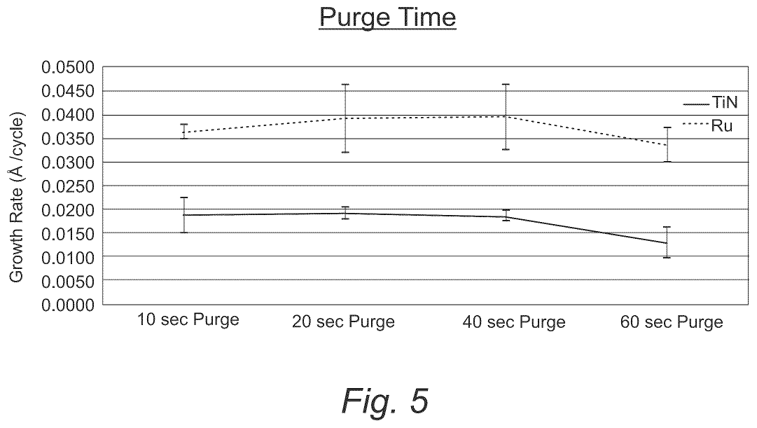

FIG. 5 provides a plot of copper growth rate versus purge pulse time showing the effect of purge times after the copper compound pulses on the copper metal film growth. The copper films were deposited from Cu(thd)₂ (at a source temperature of 140° C.) and hydrazine at a temperature of 250° C. for 1000 cycles. Each pulse of Cu(thd)₂, was set to about 6 seconds. After each pulse of Cu(thd)₂, a purge of about 10 s is applied. After each hydrazine pulse, a purge pulse of about 10 seconds is applied. Co showed consistent XRF response from 20-60 second purge times. All other substrates showed little XRF change in response to purge time changes.

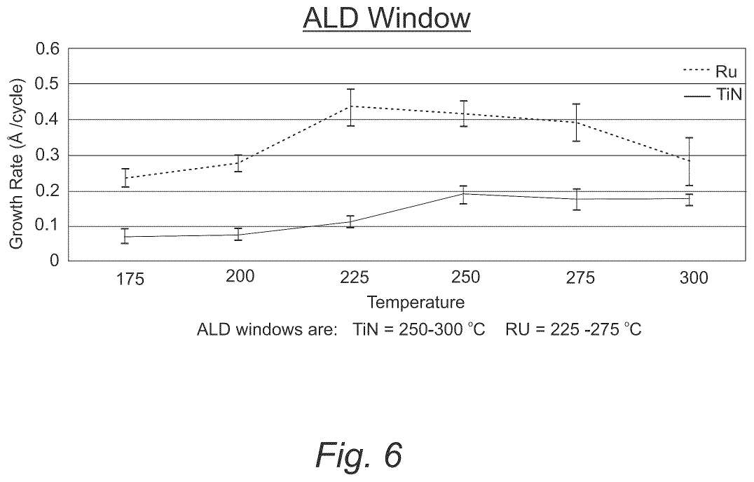

FIG. 6 provides plots of copper metal film growth rate versus temperature on a Ru layer and a TiN layer to demonstrate the ALD window. The TiN and Ru layers are deposited by ALD. The copper films were deposited from Cu(thd)₂ (at a source temperature of 140° C.) and hydrazine for 1000 cycles. Each pulse of Cu(thd)₂, was set to about 6 seconds. After each pulse of Cu(thd)₂, a purge of about 10 s is applied. Each pulse of hydrazine was set to about 0.1 seconds. After each hydrazine pulse, a purge pulse of about 10 seconds is applied. The plots suggest an ALD window of 250 to 275° C. for TiN and 225 to 275° C. for Ru.

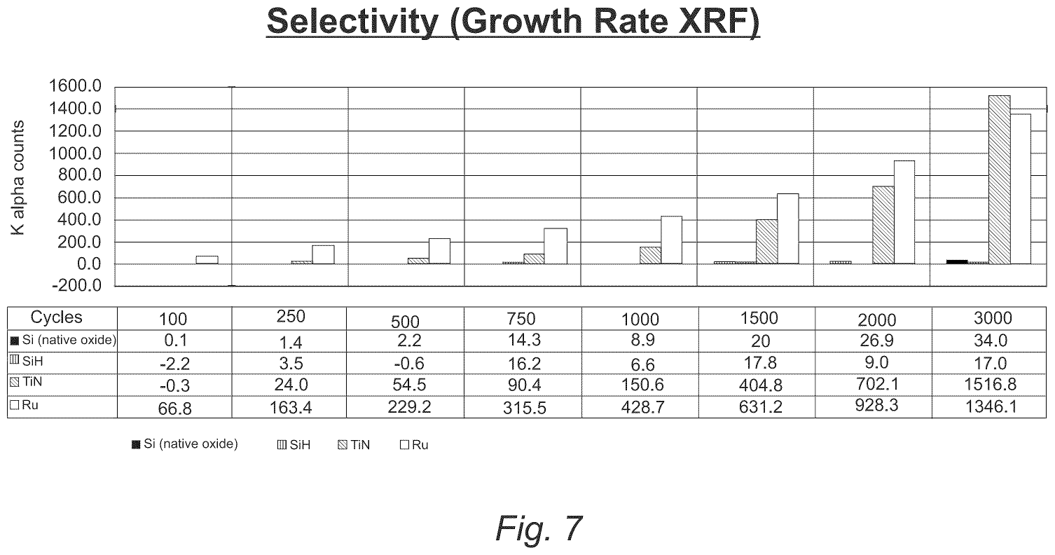

FIG. 7 provides a bar chart showing the selective deposition of copper metal films on various substrates. The bar chart provides the XRF Kα count difference for various substrates at 200° C., 225° C., 250° C., and 275° C. The copper films were deposited from Cu(thd)₂ (at a source temperature of 140° C.) and hydrazine. Each pulse of Cu(thd)₂, was set to about 6 seconds. After each Cu(thd)₂ pulse, a purge of about 10 s is applied. Each pulse of hydrazine was set to about 0.1 seconds. After each hydrazine pulse, a purge pulse of about 10 seconds is applied. Based on XRF counts, selective growth is observed on Ru and TiN.

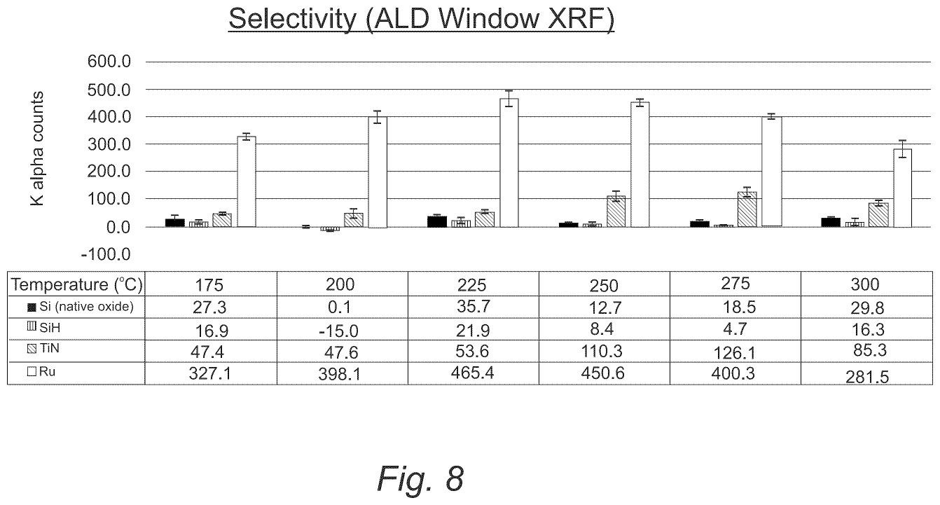

FIG. 8 provides a bar chart showing the selective deposition of copper metal films on various substrates as a function of the number of ALD cycles. The copper films were deposited from Cu(thd)₂ (at a source temperature of 140° C.) and hydrazine at a temperature of 250° C. Each pulse of Cu(thd)₂, was set to about 6 seconds. After each pulse of Cu(thd)₂, a purge of about 10 s is applied. Each pulse of hydrazine was set to about 0.1 seconds. After each hydrazine pulse, a purge pulse of about 10 seconds is applied. Based on XRF counts, selective growth is observed on Ru and TiN.

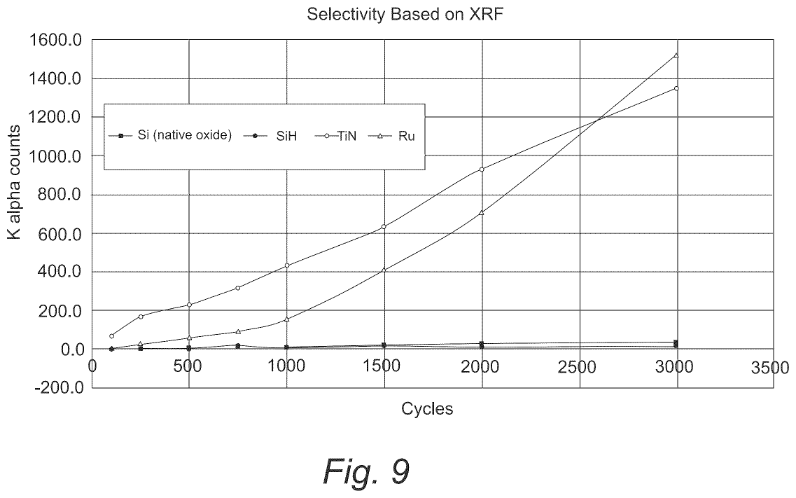

FIG. 9 plots K alpha counts versus the number of cycles for copper metal films grown on silicon, SiH, TiN, and Ru by ALD. Based on the plots, selective growth is observed on Ru and TiN.

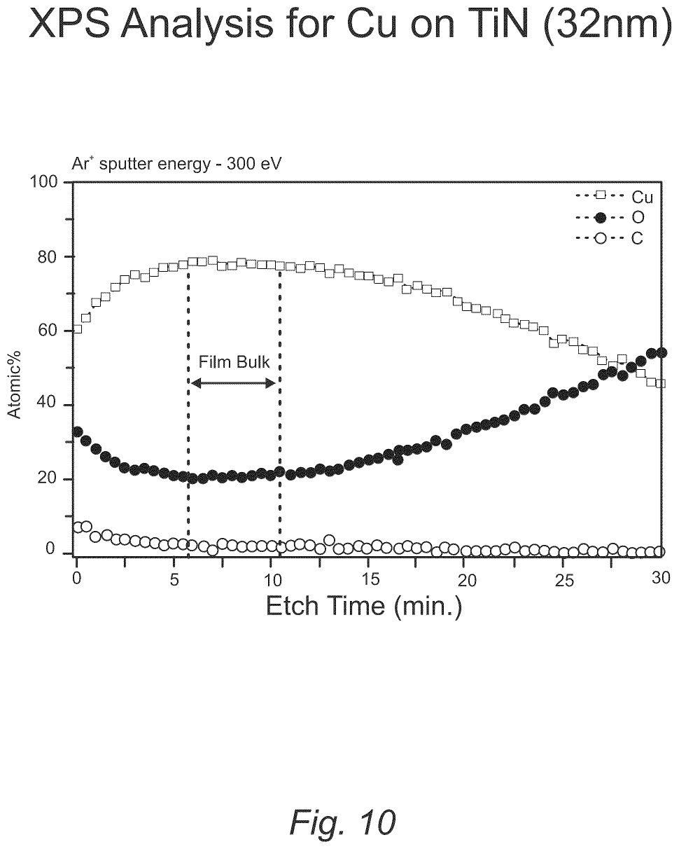

FIG. 10 provides XPS analysis for copper deposition on TiN. The copper films were deposited from Cu(thd)₂ (at a source temperature of 140° C.) and hydrazine at 250° C. for 1000 cycles. Each pulse of Cu(thd)₂, was set to about 6 seconds. After each Cu(thd)₂ pulse, a purge of about 10 s is applied. Each pulse of hydrazine was set to about 0.1 seconds. After each hydrazine pulse, a purge pulse of about 10 seconds is applied. The analysis revealed bout 77.9 atomic percent Cu, 20.6 atomic percent 0, and 1.5 atomic percent C in the bulk region.

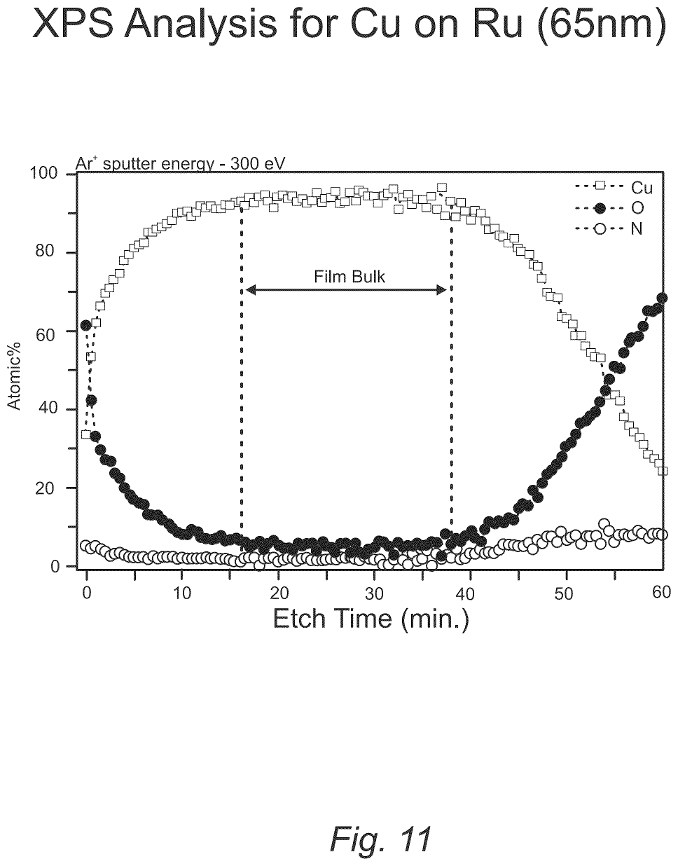

FIG. 11 provides XPS analysis for copper deposition on a 65 nm Ru layer. The copper films were deposited from Cu(thd)₂ (at a source temperature of 140° C.) and hydrazine at 250° C. for 1000 cycles. Each pulse of Cu(thd)₂, was set to about 6 seconds. After each Cu(thd)₂ pulse, a purge of about 10 s is applied. Each pulse of hydrazine was set to about 0.1 seconds. After each hydrazine pulse, a purge pulse of about 10 seconds is applied. The analysis revealed bout 93.1 atomic percent Cu, 5.2 atomic percent 0, and 1.7 atomic percent N in the bulk region.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for depositing a copper metal coating, the method comprising:
providing a substrate that includes a first face and a second face, the first face having at least one exposed surface composed of a metallic material and at least one exposed surface composed of a non-metallic material; and
contacting the substrate with a vapor of a copper-containing compound and hydrazine vapor or an alkyl-substituted hydrazine at a sufficient temperature to preferentially form the copper metal coating on the at least one exposed surface composed of a metallic material as compared to the at least one exposed surface composed of a non-metallic material.

2. The method of claim 1, wherein the first face defines a plurality of macrostructures, microstructures, and/or nanostructures.

3. The method of claim 1, wherein the first face defines a plurality of nanofeatures that are selectively filled and/or coated with the copper metal coating.

4. The method of claim 1, wherein the first face defines a plurality of dimples of metallic material that are part of electrically conductive vias.

5. The method of claim 4, further comprising polishing the first face to form the plurality of dimples before contacting the substrate with a vapor of a copper-containing compound and hydrazine.

6. The method of claim 1, wherein the substrate is part of a first microelectronic device.

7. The method of claim 6, further comprising attaching the first microelectronic device to a second microelectronic device such that copper metal coating aligns with an electrically conductive layer in the second microelectronic device wherein the copper metal coating is configured to mitigate slight misalignments between layers.

8. The method of claim 1, wherein a ratio of copper metal thickness on the at least one exposed surface composed of a metallic material to copper metal thickness on the at least one exposed surface composed of a non-metallic material is greater than 10:1.

9. The method of claim 1, wherein a ratio of copper metal thickness on the at least one exposed surface composed of a metallic material to copper metal thickness on the at least one exposed surface composed of a non-metallic material is greater than 4:1.

10. The method of claim 1, wherein the metallic material is selected from the group consisting of copper, cobalt, TiN, TaN, and ruthenium.

11. The method of claim 1, wherein the non-metallic material is selected from the group consisting of high-K materials, low K-materials, ultra-low-K materials, and combinations thereof.

12. The method of claim 1, wherein the non-metallic material is selected from the group consisting of silicon with a native oxide, silicon with surface Si—H bonds, silicon oxide, low K-materials, and combinations thereof.

13. The method of claim 1 comprising an atomic layer deposition cycle including:
a) contacting the substrate with or without a coating thereon with the hydrazine vapor; and
b) contacting the substrate with or without a coating thereon with the vapor of the copper-containing compound, wherein steps a) and b) are repeated for a sufficient number of cycles to form a predetermined thickness of the copper metal coating.

14. The method of claim 13, where the atomic layer deposition cycle further includes a first purging step with an inert gas after step a) and a second purging step with an inert gas after step b).

15. The method of claim 1, wherein the sufficient temperature is from 150 to 300° C.

16. The method of claim 1, wherein the copper-containing compound is a Cu(I) or Cu(II) diketonate.

17. The method of claim 1, wherein the copper-containing compound is selected from the group consisting of Cu(II) 2,6-dimethylheptane-3,5-dionate; Cu(II) 2,2,6,6-tetramethylheptane-3,5-dionate; Cu(II) pentane-2,4-dionate; Cu(II) 6,6,7,7,8,8,8-heptafluoro-2,2-dimethyloctane-3,5-dionate; Cu(II) 1,1,1-trifluoropentane-2,4-dionate; Cu(II) 1,1,1,5,5,5-hexafluoropentane-2,4-dionate; Cu(II) 1,1,1,5,5,6,6,6-octafluorohexane-2,4-dionate; Cu(II) 4,4,4-trifluoro-1-phenylbutane-1,3-dionate; Cu(II) 1-phenylbutane-1,3-dionate; Cu(II) 1,1,1-trifluoro-5,5-dimethylhexane-2,4-dionate; and combinations thereof.

18. The method of claim 1, wherein the copper-containing compound is selected from the group consisting of Cu(I) 2,6-dimethylheptane-3,5-dionate; Cu(I) 2,2,6,6-tetramethylheptane-3,5-dionate; Cu(I) pentane-2,4-dionate; Cu(I) 6,6,7,7,8,8,8-heptafluoro-2,2-dimethyloctane-3,5-dionate; Cu(I) 1,1,1-trifluoropentane-2,4-dionate; Cu(I) 1,1,1,5,5,5-hexafluoropentane-2,4-dionate; Cu(I) 1,1,1,5,5,6,6,6-octafluorohexane-2,4-dionate; Cu(I) 4,4,4-trifluoro-1-phenylbutane-1,3-dionate; Cu(I) 1-phenylbutane-1,3-dionate; Cu(I) 1,1,1-trifluoro-5,5-dimethylhexane-2,4-dionate; and combinations thereof.

19. The method of claim 1, wherein the copper-containing compound is a Cu(I) diketonate that includes a stabilizing ligand.

20. The method of claim 19, wherein the stabilizing ligand is CH₂=CHSiMe₃.

21. The method of claim 1, wherein the copper-containing compound and the hydrazine vapor or an alkyl-substituted hydrazine are used in a chemical vapor deposition (CVD) reactor.

22. A method for depositing a coating on a surface of a substrate, the substrate having a first face and a second face, the first face having at least one exposed surface composed of a metallic material and at least one exposed surface composed of a non-metallic material, the method including an atomic layer deposition cycle comprising:
a) contacting the substrate with or without a coating thereon with a hydrazine vapor and/or an alkyl-substituted hydrazine; and
b) contacting the substrate with or without a coating thereon with a vapor of a copper-containing compound at a temperature from 150 to 300° C. to preferentially form a copper metal coating on the surface composed of a metallic material as compared to the exposed surface composed of a non-metallic material, wherein steps a) and b) are repeated for a sufficient number of cycles to form a predetermined thickness of the copper metal coating.

23. The method of claim 22, where the atomic layer deposition cycle further includes a first purging step with an inert gas after step a) and a second purging step with an inert gas after step b).

24. The method of claim 22, wherein the copper-containing compound is selected from the group consisting of Cu(II) 2,6-dimethylheptane-3,5-dionate; Cu(II) 2,2,6,6-tetramethylheptane-3,5-dionate; Cu(II) pentane-2,4-dionate; Cu(II) 6,6,7,7,8,8,8-heptafluoro-2,2-dimethyloctane-3,5-dionate; Cu(II) 1,1,1-trifluoropentane-2,4-dionate; Cu(II) 1,1,1,5,5,5-hexafluoropentane-2,4-dionate; Cu(II) 1,1,1,5,5,6,6,6-octafluorohexane-2,4-dionate; Cu(II) 4,4,4-trifluoro-1-phenylbutane-1,3-dionate; Cu(II) 1-phenylbutane-1,3-dionate; Cu(II) 1,1,1-trifluoro-5,5-dimethylhexane-2,4-dionate; and combinations thereof.

25. The method of claim 22, wherein the copper-containing compound is selected from the group consisting of Cu(I) 2,6-dimethylheptane-3,5-dionate; Cu(I)2,2,6,6-tetramethylheptane-3,5-dionate; Cu(I) pentane-2,4-dionate; Cu(I) 6,6,7,7,8,8,8-heptafluoro-2,2-dimethyloctane-3,5-dionate; Cu(I) 1,1,1-trifluoropentane-2,4-dionate; Cu(I) 1,1,1,5,5,5-hexafluoropentane-2,4-dionate; Cu(I) 1,1,1,5,5,6,6,6-octafluorohexane-2,4-dionate; Cu(I) 4,4,4-trifluoro-1-phenylbutane-1,3-dionate; Cu(I) 1-phenylbutane-1,3-dionate; Cu(I) 1,1,1-trifluoro-5,5-dimethylhexane-2,4-dionate; and combinations thereof. Ditto the alkene ligand comment above for Cu(I) precursors.

26. The method of claim 22, wherein the coper-containing compound is a Cu(I) diketonate that includes a stabilizing ligand.

27. The method of claim 26, wherein the stabilizing ligand is CH₂=CHSiMe₃.

28. The method of claim 22, wherein the first face defines a plurality of macrostructures, microstructures, and/or nanostructures.

29. The method of claim 22, wherein the first face defines a plurality of nanofeatures that are selectively filled and/or coated with the copper metal coating.

30. The method of claim 22, wherein the first face defines a plurality of dimples of metallic material that are part of electrically conductive vias.

31. The method of claim 30, further comprising polishing the first face to form the plurality of dimples prior to the atomic layer deposition cycle.

32. The method of claim 22, wherein the substrate is part of a first microelectronic device.

33. The method of claim 22, further comprising attaching the first microelectronic device to a second microelectronic device such that copper metal coating aligns with an electrically conductive layer in the second microelectronic device wherein the copper metal coating is configured to mitigate slight misalignments between layers.

34. The method of claim 22, wherein a ratio of copper metal thickness on the at least one exposed surface composed of a metallic material to copper metal thickness on the at least one exposed surface composed of a non-metallic material is greater than 10:1.

35. The method of claim 22, wherein a ratio of copper metal thickness on the at least one exposed surface composed of a metallic material to copper metal thickness on the at least one exposed surface composed of a non-metallic material is greater than 4:1.

36. The method of claim 22, wherein the metallic material is selected from the group consisting of copper, cobalt, TiN, TaN, and ruthenium.

37. The method of claim 32, wherein a ratio of copper metal thickness on the at least one exposed surface composed of a metallic material to copper metal thickness on the at least one exposed surface composed of a non-metallic material is less than 4:1.

38. The method of claim 32, wherein the metallic material is selected from the group consisting of copper, cobalt, TiN, and ruthenium.

39. A method for depositing a copper metal coating, the method comprising:
providing a substrate that includes a first face and a second face, the first face having at least one exposed surface composed of a metallic material and at least one exposed surface composed of a non-metallic material; and
contacting the substrate with a vapor of a copper-containing compound and an alkyl amine and/or ammonia vapor and/or an alkyl-substituted hydrazine at a sufficient temperature to preferentially form the copper metal coating on the at least one exposed surface composed of a metallic material as compared to the at least one exposed surface composed of a non-metallic material.
